(19) United States
(12) Patent Application Publication
(10) Pub. No.: US 2026/0261249 A1
(43) Pub. Date: Sep. 3, 2026

(54) COMBINER/SPLITTER

(71) Applicant: Qorvo US, Inc., Greensboro, NC (US)

(72) Inventors: Timothy M. Gittemeier, Plano, TX (US); Michael Roberg, Evergreen, CO (US)

(21) Appl. No.: 19/653,287

(22) Filed: Apr. 21, 2026

Related U.S. Application Data
(62) Division of application No. 18/061,210, filed on Dec. 2, 2022, now Pat. No. 12,652,014.
(60) Provisional application No. 63/301,123, filed on Jan. 20, 2022.

(51) Int. Cl. H03H 7/48; H01P 5/16; H04B 1/40

(52) U.S. Cl. CPC H03H 7/487; H01P 5/16; H04B 1/40

(57) ABSTRACT

A combiner/splitter is disclosed having a first trifilar transformer having a first outer transmission element electrically connected between a first port node and a first intermediate node. A second trifilar transformer has a second outer transmission element electrically connected between the first intermediate node and a second port node. A third trifilar transformer has a third outer transmission element electrically connected between the first port node and a second intermediate node. A fourth trifilar transformer has a fourth outer transmission element electrically connected between the second intermediate node and a third port node.

### RELATED APPLICATIONS

This application is a divisional of U.S. Patent Application Serial No. 18/061,210, filed December 2, 2022, which claims the benefit of provisional patent application serial number 63/301,123, filed January 20, 2022, the disclosures of which are hereby incorporated herein by reference in their entireties.

### FIELD OF THE DISCLOSURE

The present disclosure relates to combiners/splitters and in particular to broadband power combiners/splitters that are fabricated into integrated circuits.

### BACKGROUND

Radio frequency (RF) power combiners and RF power splitters, including microwave power combiners/splitters, are used extensively in RF and microwave communications systems. Several types of traditional power combiners/splitters such as Wilkinson-type power combiners/splitters are available. However, such traditional power combiners/splitters are lacking in one or more desirable fifth-generation (5G) attributes that include, but are not limited to, smaller size, greater bandwidth, and higher power handling. Thus, there remains a need for power combiners/splitters that meet newer and more desirable 5G attributes.

### SUMMARY

A combiner/splitter is disclosed having a first trifilar transformer having a first outer transmission element electrically connected between a first port node and a first intermediate node. A second trifilar transformer has a second outer transmission element electrically connected between the first intermediate node and a second port node. A third trifilar transformer has a third outer transmission element electrically connected between the first port node and a second intermediate node. A fourth trifilar transformer has a fourth outer transmission element electrically connected between the second intermediate node and a third port node

The present combiner/splitter employs the four trifilar transformers and at least one resistor to create a broadband combiner/splitter with high insolation. As disclosed, the combiner/splitter is an in-phase power combiner/splitter that has low insertion loss and high power handling. The combiner/splitter has excellent phase and magnitude balance across wide bandwidth. A die on which the combiner/splitter is fabricated may have a relatively compact size using flip chip or bond wires to combine two power amplifiers in a package.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic of an exemplary embodiment of a combiner/splitter that is structured in accordance with the present disclosure.

FIG. 2 is a diagram depicting a layout for an integrated circuit die of an exemplary embodiment of the combiner/splitter 10 that is structured in accordance with the present disclosure.

FIG. 3 is a graph depicting losses and isolation versus frequency for the combiner/splitter.

FIG. 4 is a graph depicting losses and phase angle versus frequency for the combiner/splitter.

FIG. 5 is a diagram showing how the disclosed combiner/splitter may interact with user elements such as wireless communication devices.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

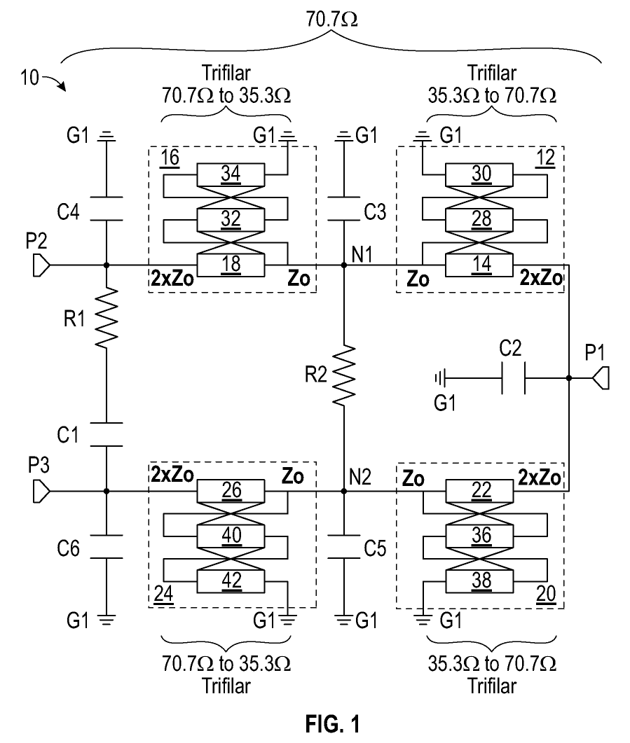

FIG. 1 is a schematic of an exemplary embodiment of a combiner/splitter 10, having a first trifilar transformer 12 having a first outer transmission element 14 electrically connected between a first port node P1 and a first intermediate node N1. A second trifilar transformer 16 has second outer transmission element 18 electrically connected between the first intermediate node N1 and a second port node P2. A third trifilar transformer 20 has a third outer transmission element 22 electrically connected between the first port node P1 and a second intermediate node N2. A fourth trifilar transformer 24 has a fourth outer transmission element 26 electrically connected between the second intermediate node N2 and a third port node P3.

The first trifilar transformer 10 has a first middle transmission element 28 and a first inner transmission element 30 that are electrically connected in series between the first intermediate node N1 and a fixed voltage node G1. The first middle transmission element 28 is arranged relative to the first outer transmission element 14 to magnetically couple with the first outer transmission element 14, and the first inner transmission element 30 is arranged relative to the first middle transmission element 28 to magnetically couple with the first middle transmission element 28.

The second trifilar transformer 16 has a second middle transmission element 32 and a second inner transmission element 34 that are electrically connected in series between the first intermediate node N1 and the fixed voltage node G1. The second middle transmission element 32 is arranged relative to the second outer transmission element 18 to magnetically couple with the second outer transmission element 18, and the second inner transmission element 34 is arranged relative to the second middle transmission element 32 to magnetically couple with the second middle transmission element 32.

The third trifilar transformer 20 has a third middle transmission element 36 and a third inner transmission element 38 that are electrically connected in series between the second intermediate node N2 and the fixed voltage node G1, The third middle transmission element 36 is arranged relative to the third outer transmission element 22 to magnetically couple with the third outer transmission element 22, and the third inner transmission element 38 is arranged relative to the third middle transmission element 36 to magnetically couple with the third middle transmission element 36.

The fourth trifilar transformer 20 has a fourth middle transmission element 40 and a fourth inner transmission element 42 that are electrically connected in series between the second intermediate node N2 and the fixed voltage node G1. The fourth middle transmission element 40 is arranged relative to the fourth outer transmission element 26 to magnetically couple with the fourth outer transmission element 26, and the fourth inner transmission element 42 is arranged relative to the fourth middle transmission element 40 to magnetically couple with the fourth middle transmission element 40.

A first resistor R1 and a first capacitor C1 are electrically connected in series between the second port node P2 and the third port node (P3). The first resistor R1 and the first capacitor provide high isolation between the second port node P2 and the third port node P3. In the exemplary embodiment depicted in FIG. 1, a second resistor R2 is electrically connected between the first intermediate node N1 and the second intermediate node N2 to provide further isolation between a first signal path that carries radio frequency (RF) signals between the first port node P1 and the second port node P2 and a second signal path that carries RF signals between the first port node P1 and the third port node P3. A second capacitor C2 is electrically connected between the first port node P1 and the fixed voltage node G1. A third capacitor C3 is electrically connected between the first intermediate node N1 and the fixed voltage node G1. A fourth capacitor C4 is electrically connected between the second port node P2 and the fixed voltage node G1. A fifth capacitor C5 is electrically connected between the second intermediate node N2 and the fixed voltage node G1. A sixth capacitor C6 is electrically connected between the third port node P3 and the fixed voltage node G1. Each of the capacitors C2-C6 improves return loss for the splitter/combiner 10. The fixed voltage node G1 depicted in FIG. 1 is at ground potential.

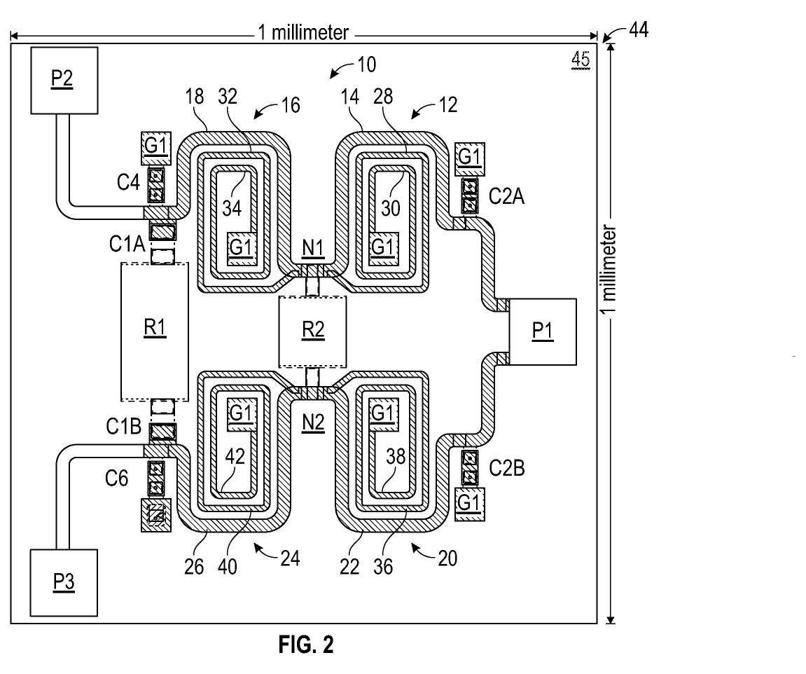

FIG. 2 is a diagram depicting a layout for an integrated circuit die 44 of an exemplary embodiment of the combiner/splitter 10 structured in accordance with the present disclosure. The exemplary integrated circuit die 44 includes a substrate 45 onto which the combiner/splitter 10 is fabricated. The exemplary substrate 45 is 1 millimeter by 1 millimeter. Materials for the substrate 45 may include but are not limited to semiconductor materials such as gallium nitride, alumina, and printed circuit board substrate materials. In the exemplary embodiment depicted in FIG. 2, the first capacitor C1 depicted symbolically in FIG. 1 is split into two physical capacitors C1A and C1B. Similarly, the second capacitor C2 depicted symbolically in FIG. 1 is split into two physical capacitors C2A and C2B as shown in FIG. 2. The exemplary embodiment depicted in FIG. 2 does not show the third capacitor C3 and the fifth capacitor C5 which are shown symbolically in FIG. 1, but the third capacitor C3 may be electrically connected between the first node N1 and the ground node G1, and the fifth capacitor C5 may be added between the second node N2 and the ground node G1.

Conductive lines making up the outer transmission elements 14, 18, 22, and 26 may be at least 20 micrometers wide. The middle transmission elements 28, 32, 36, and 40 and the inner transmission elements 30, 34, 38, and 42 may be less wide than the outer transmission elements 14, 18, 22, and 26. Moreover, the trifilar transformers may be fabricated from standard metal layers such as M0/MIM/M1/M2/MX2. The resistors R1 and R2 may be fabricated to be 100 micrometers wide for power handling.

The combiner/splitter 10 is usable for wideband RF signal combining and splitting. The combiner/splitter 10 provides higher isolation that is greater than 15 dB across 20 GHz of bandwidth. Moreover, the combiner/splitter 10 provides low insertion loss that is less than 0.6 dB across 20 GHz of bandwidth. The combiner/splitter 10 substantially maintains zero phase and magnitude imbalance across 20 GHz of bandwidth. Electrostatic discharge protection is grounded through a via to ground G1. The combiner/splitter 10 may be bumped and mounted on a laminate, thereby avoiding bond wire inductance.

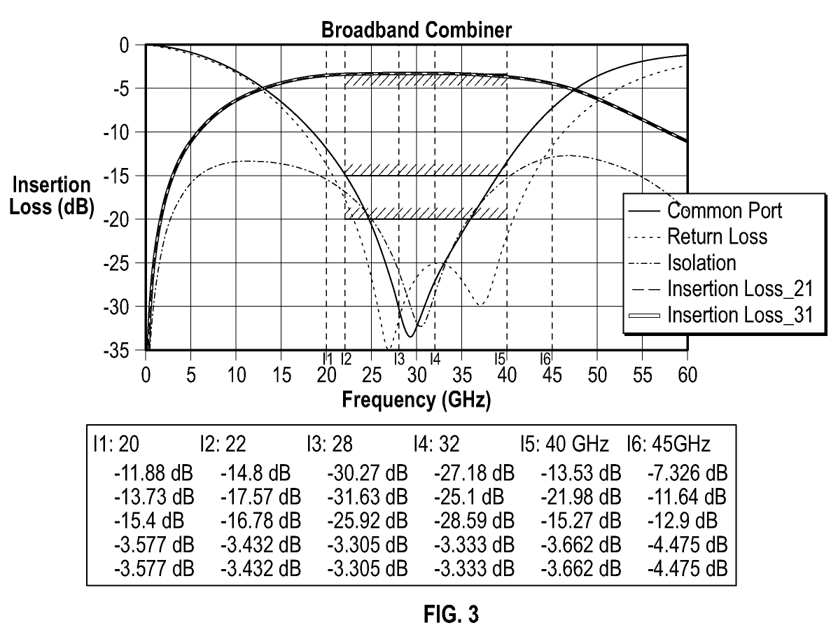

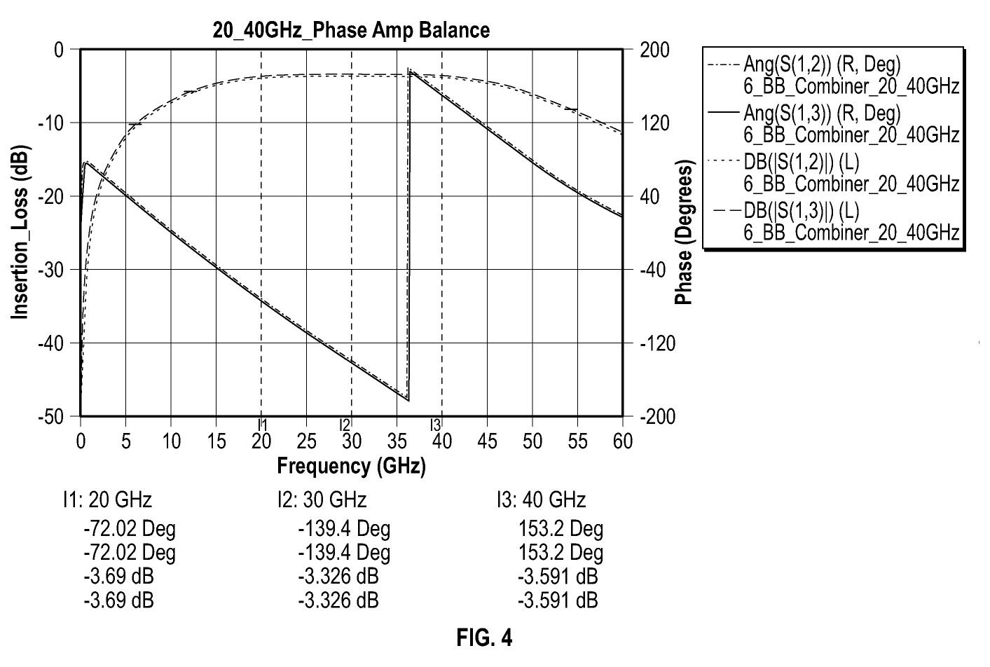

FIG. 3 is a graph depicting losses and isolation versus frequency for the combiner/splitter 10. Note that the combiner/splitter 10 provides greater than 25 dB isolation from 28 GHz to 32 GHz. Also notice that the combiner/splitter 10 has no more than 0.3 dB loss from 28 GHz to 32 GHz. FIG. 4 is a graph depicting losses and phase angle versus frequency for the combiner/splitter 10.

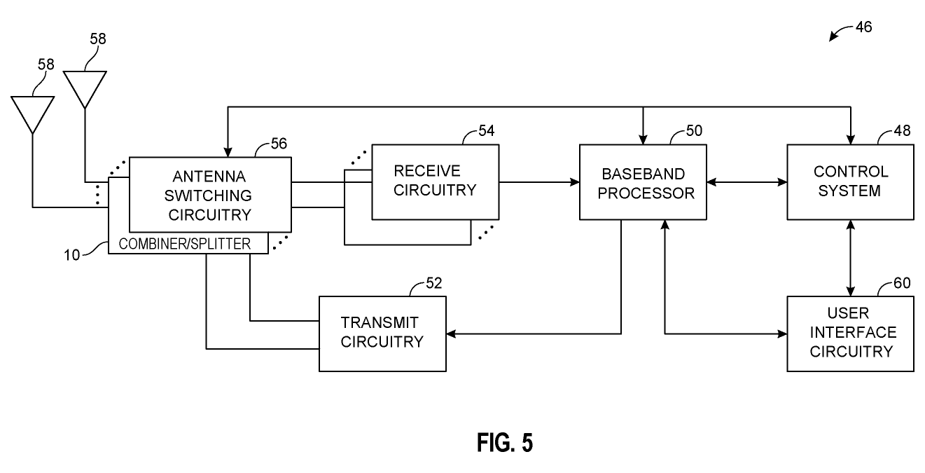

FIG. 5 is a diagram showing how the disclosed combiner/splitter 10 may interact with user elements such as wireless communication devices. With reference to FIG. 5, the concepts described above may be implemented in various types of wireless communication devices or user elements 46, such as mobile terminals, smart watches, tablets, computers, navigation devices, access points, and the like that support wireless communications, such as cellular, wireless local area network (WLAN), Bluetooth, and near-field communications. The user elements 46 generally include a control system 48, a baseband processor 50, transmit circuitry 52, receive circuitry 54, antenna switching circuitry 56, multiple antennas 58, and user interface circuitry 60 that includes the combiner/splitter 10 (FIG. 2). The receive circuitry 54 receives radio frequency signals via the antennas 58 and through the antenna switching circuitry 56 from one or more basestations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams.

The baseband processor 50 processes the digitized received signal to extract the information or data bits conveyed in the received signal. This processing typically comprises demodulation, decoding, and error correction operations. The baseband processor 50 is generally implemented in one or more digital signal processors and application-specific integrated circuits.

For transmission, the baseband processor 50 receives digitized data, which may represent voice, data, or control information, from the control system 48, which it encodes for transmission. The encoded data is output to the transmit circuitry 52, where it is used by a modulator to modulate a carrier signal that is at a desired transmit frequency or frequencies. A power amplifier will amplify the modulated carrier signal to a level appropriate for transmission and deliver the modulated carrier signal to the antennas 58 through the antenna switching circuitry 56. The antennas 58 and the replicated transmit circuitry 52 and receive circuitry 52 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. Circuitry comprising:
a first trifilar transformer having a first outer transmission element electrically coupled between a first port node and a first intermediate node;
a second trifilar transformer having a second outer transmission element electrically coupled between the first intermediate node and a second port node;
a third trifilar transformer having a third outer transmission element electrically coupled between the first port node and a second intermediate node; and
a fourth trifilar transformer having a fourth outer transmission element electrically coupled between the second intermediate node and a third port node, wherein the second port node and the third port node are different nodes through which different signals from different external sources can be received, and the first trifilar transformer, the second trifilar transformer, the third trifilar transformer, and the fourth trifilar transformer are configured to provide an overall insertion loss of no more than 0.3 dB from 28 GHz to 32 GHz.

2. The circuitry of claim 1 further comprising a first resistor and a first capacitor electrically coupled in series between the second port node and the third port node.

3. The circuitry of claim 1 further comprising a second resistor electrically coupled between the first intermediate node and the second intermediate node.

4. The circuitry of claim 1 wherein a capacitor is electrically coupled between each of the first port node, the first intermediate node, the second port node, the second intermediate node, and the third port node and ground.

5. The circuitry of claim 1 wherein a substrate on which the circuitry is fabricated has dimensions of 1 millimeter by 1 millimeter.

6. The circuitry of claim 1 wherein each of the first, second, third, and fourth outer transmission elements has a width of at least 20 micrometers, and wherein middle transmission elements and inner transmission elements of each trifilar transformer are narrower than their respective outer transmission element.

7. The circuitry of claim 1 wherein each of the first, second, third, and fourth trifilar transformers is fabricated from integrated circuit metal layers.

8. The circuitry of claim 2 wherein the first resistor has a width of approximately 100 micrometers for power handling.

9. The circuitry of claim 3 wherein the second resistor has a width of approximately 100 micrometers for power handling.

10. The circuitry of claim 1 wherein the circuitry is flip-chip mounted on a laminate substrate using bumps to avoid bond wire inductance.

11. The circuitry of claim 1 wherein the circuitry provides greater than 25 dB of isolation between the second port node and the third port node across a frequency range from 28 GHz to 32 GHz.

12. The circuitry of claim 5 wherein the substrate comprises gallium nitride.

13. The circuitry of claim 5 wherein the substrate comprises alumina.

14. A circuitry comprising:
a first trifilar transformer having a first outer transmission element electrically coupled between a first port node and a first intermediate node;
a second trifilar transformer having a second outer transmission element electrically coupled between the first intermediate node and a second port node;
a third trifilar transformer having a third outer transmission element electrically coupled between the first port node and a second intermediate node; and
a fourth trifilar transformer having a fourth outer transmission element electrically coupled between the second intermediate node and a third port node, wherein the second port node and the third port node are different nodes through which different signals from different external sources can be received, and the first trifilar transformer, the second trifilar transformer, the third trifilar transformer, and the fourth trifilar transformer are fabricated from metal layers and integrated into an integrated circuit die.

15. The circuitry of claim 14 further comprising a first resistor and a first capacitor electrically coupled in series between the second port node and the third port node.

16. The circuitry of claim 14 further comprising a second resistor electrically coupled between the first intermediate node and the second intermediate node.

17. The circuitry of claim 14 further comprising a plurality of capacitors, wherein at least one capacitor is electrically coupled between each of the first port node, the first intermediate node, the second port node, the second intermediate node, and the third port node and ground.

18. The circuitry of claim 14 wherein an integrated circuit die on which the circuitry is fabricated has dimensions of 1 millimeter by 1 millimeter.

19. The circuitry of claim 14 wherein each of the first, second, third, and fourth outer transmission elements has a width of at least 20 micrometers, and wherein each of the first, second, third, and fourth trifilar transformers further comprises a middle transmission element and an inner transmission element, wherein each middle transmission element and each inner transmission element is narrower than its respective outer transmission element.

20. The circuitry of claim 15 wherein the first resistor has a width of approximately 100 micrometers for power handling.

21. The circuitry of claim 16 wherein the second resistor has a width of approximately 100 micrometers for power handling.

22. The circuitry of claim 14 wherein the integrated circuit die is flip-chip mounted on a laminate substrate using bumps to avoid bond wire inductance.

23. The circuitry of claim 14 wherein the circuitry provides greater than 25 dB of isolation between the second port node and the third port node across a frequency range from 28 GHz to 32 GHz.

24. The circuitry of claim 14 wherein the integrated circuit die comprises gallium nitride or alumina.

25. A method of combining or splitting radio frequency (RF) signals using circuitry having a first port node, a second port node, and a third port node, the method comprising:
routing an RF signal between the first port node and the second port node via a first signal path comprising a first trifilar transformer and a second trifilar transformer; and
routing an RF signal between the first port node and the third port node via a second signal path comprising a third trifilar transformer and a fourth trifilar transformer,
wherein the first, second, third, and fourth trifilar transformers are configured to provide an overall insertion loss of no more than 0.3 dB from 28 GHz to 32 GHz.

26. The method of claim 25 further comprising providing high isolation between the second port node and the third port node via a first resistor and a first capacitor electrically coupled in series between the second port node and the third port node.

27. The method of claim 25 further comprising providing isolation between the first signal path and the second signal path via a second resistor electrically coupled between a first intermediate node of the first signal path and a second intermediate node of the second signal path.

28. The method of claim 25 further comprising improving return loss by coupling at least one capacitor between each of the first port node, the second port node, and the third port node and ground.

29. The method of claim 25 wherein routing the RF signals provides greater than 25 dB of isolation between the second port node and the third port node across a frequency range from 28 GHz to 32 GHz.

30. A method of operating a wireless communication device, the method comprising:
receiving, at one or more antennas, an RF signal;
routing the RF signal through antenna switching circuitry to a circuitry; and
splitting or combining the RF signal using the circuitry, wherein the circuitry comprises:
a first trifilar transformer having a first outer transmission element electrically coupled between a first port node and a first intermediate node;
a second trifilar transformer having a second outer transmission element electrically coupled between the first intermediate node and a second port node;
a third trifilar transformer having a third outer transmission element electrically coupled between the first port node and a second intermediate node; and
a fourth trifilar transformer having a fourth outer transmission element electrically coupled between the second intermediate node and a third port node.

31. The method of claim 30 wherein the circuitry is fabricated on an integrated circuit die that is flip-chip mounted on a laminate substrate to avoid bond wire inductance.

32. A wireless communication device comprising the circuitry of claim 1 further comprising:
one or more antennas; and
antenna switching circuitry coupled between the one or more antennas and the circuitry.

33. A wireless communication device comprising the circuitry of claim 14 further comprising:
one or more antennas; and
antenna switching circuitry coupled between the one or more antennas and the circuitry.
